(19) United States
(12) Patent Application Publication
(10) Pub. No.: US 2011/0204355 A1
(43) Pub. Date: Aug. 25, 2011

(54) ZINC OXIDE BASED SUBSTRATE AND METHOD FOR MANUFACTURING ZINC OXIDE BASED SUBSTRATE

(75) Inventors: Takao SUZUKI, Tokyo (JP); Ken NAKAHARA, Kyoto-shi (JP); Hiroyuki YUJI, Kyoto-shi (JP)

(73) Assignees: ROHM CO., LTD., Kyoto-shi (JP); MITSUBISHI CHEMICAL CORPORATION, Tokyo (JP); TOKYO DENPA CO., LTD., Tokyo (JP)

(21) Appl. No.: 12/869,227

(22) Filed: Aug. 26, 2010

(30) Foreign Application Priority Data
Aug. 28, 2009 (JP) 2009-198161

(51) Int. Cl. H01L 29/22; C30B 7/10

(52) U.S. Cl. 257/43; 117/71; 257/E29.094

(57) ABSTRACT

A zinc oxide based substrate satisfies a condition that impurities Si, C, Ge, Sn, and Pb which are Group IV elements each have a concentration of 1×10¹⁷ cm⁻³ or less. More preferably, the zinc oxide based substrate 2 satisfies a condition that impurities Li, Na, K, Rb, and Fr which are Group I elements each have a concentration of 1×10¹⁶ cm⁻³ or less. The impurity concentration of a zinc oxide based semiconductor grown on the zinc oxide based substrate can be reduced in this manner.

### CROSS REFERENCE TO RELATED APPLICATIONS AND INCORPORATION BY REFERENCE

This application is based upon and claims the benefit of prior Japanese Patent Application P2009-198161 filed on Aug. 28, 2009; the entire contents of which are incorporated by reference herein.

### BACKGROUND OF THE INVENTION

1. Field of the Invention

The present invention relates to a zinc oxide based substrate for growing a zinc oxide based semiconductor thereon and also relates to a method of manufacturing the substrate.

2. Description of the Related Art

Attention has been drawn on a zinc oxide based semiconductor, which has a simple composition, is of low cost, and has a wide direct band gap. Such a zinc oxide based semiconductor is employed for a TFT, a surface acoustic wave device, a light emitting diode, a laser, or the like. Further, the study on the zinc oxide based semiconductor has been more active since light emission of the zinc oxide based semiconductor is confirmed, as described in Non-Patent Document 1 (A. Tsukazaki et al., Japanese Journal of Applied Physics, Vol. 44, No. 21, (2005), pp. L643-L645) and Non-Patent Document 2 (A. Tsukazaki et al., Nature Materials, Vol. 4, (2005) p. 42.).

In this respect, the zinc oxide based semiconductor contains oxygen which can form compounds together with various elements, and is a highly chemically reactive element. For this reason, manufacturing the zinc oxide based semiconductor involves a problem that the concentration of an impurity such as Li or Si is very difficult to control. Particularly, the zinc oxide based semiconductor has a tendency to easily change into n type. This causes problems that undesired impurities, which act as electron suppliers, prevent the zinc oxide based semiconductor from changing into p type, decrease carrier mobility in the deep level, diffuse during epitaxial growth, and cause other problems.

Particularly, in many cases, the zinc oxide based substrate is manufactured by the hydrothermal synthesis method in which the impurity concentration is difficult to control. For this reason, the zinc oxide based substrate has a high impurity concentration. Thus, there is a problem that the zinc oxide based semiconductor layer which is grown on the zinc oxide based substrate necessarily has a high impurity concentration. Especially, in the hydrothermal synthesis method in which the zinc oxide based substrate is manufactured by dissolving a zinc oxide based material in a LiOH solution or the like, it is known that the zinc oxide based substrate has high concentrations of impurities including Li and the like which are contained in the solution.

In view of the above problems, a technique is known in which the impurity concentration of the zinc oxide based semiconductor is controlled by reducing the impurity concentration of the zinc oxide based substrate.

Patent Document 1 (Japanese Patent Application Publication No. 2007-1787) discloses a method of manufacturing a zinc oxide based semiconductor, the method capable of reducing the Li concentration of the zinc oxide based semiconductor by growing the zinc oxide based semiconductor on a zinc oxide substrate having a Li concentration (impurity concentration) of 4×10¹⁶ cm⁻³. However, the experiment conducted by the inventors of the present application revealed that growing a zinc oxide based semiconductor on the zinc oxide substrate having the Li concentration disclosed in Patent Document 1 did not sufficiently reduce the Li concentration. Specifically, in a case where a zinc oxide based semiconductor was grown on a zinc oxide substrate having a Li concentration of about 2×10¹⁶ cm⁻³, Li moved to the surface of the zinc oxide substrate by heating the zinc oxide substrate, and then diffused in the grown zinc oxide based semiconductor. For this reason, the grown zinc oxide based semiconductor layer had the Li concentration of 5×10¹⁶cm⁻³ to 1×10¹⁷cm⁻³. Thus, it was found that sufficient reduction of the impurity concentration was not achieved with the above method.

In this regard, Patent Document 2 (Japanese Patent Application Publication No. 2007-204324) discloses a method of manufacturing a zinc oxide single crystal having a Li concentration of 1×10¹⁶ cm⁻³ or less. It is presumable that this method achieves reduction of the Li concentration of a zinc oxide based semiconductor layer grown on a zinc oxide single crystal manufactured by the technique disclosed in Patent Document 2.

### SUMMARY OF THE INVENTION

Besides Li, however, the zinc oxide based semiconductor contains various impurities which affect device operation and the like. In other words, there is a problem that the impurity concentration in a zinc oxide based semiconductor grown on a zinc oxide based substrate is not sufficiently reduced by reducing only the Li concentration in the zinc oxide based substrate.

The present invention is made to address the above problems, and an object of the present invention is to provide a zinc oxide based substrate and a method of manufacturing a zinc oxide based substrate, the substrate and the method allowing reduction of the impurity concentration of a zinc oxide based semiconductor grown on the substrate.

In order to achieve the above object, a first aspect of the present invention is a zinc oxide based substrate including an impurity of a Group IV element of any of Si, C, Ge, Sn, and Pb, the impurity having a concentration of 1×10¹⁷ cm⁻³ or less. Note that a zinc oxide base is a concept including ZnO and MgZnO.

Moreover, a second aspect of the present invention is a zinc oxide based substrate including: an impurity of a Group I element of any of Li, Na, K, Rb, and Fr, the impurity having a concentration of 1×10¹⁶ cm⁻³ or less; and an impurity of a Group IV element of any of Si, C, Ge, Sn, and Pb, the impurity having a concentration of 1×10¹⁷ cm⁻³ or less.

Furthermore, a third aspect of the present invention is the zinc oxide based substrate according the second aspect characterized in that the Group I element is Li, and the Group IV element is Si.

In addition, a fourth aspect of the present invention is the zinc oxide based substrate according to any one of the first to third aspects characterized in that the zinc oxide based substrate is formed of MgₓZn₁₋ₓO (0≦X≦0.5).

Moreover, a fifth aspect of the present invention is method for manufacturing a zinc oxide based substrate including the step of forming an ingot made of a zinc oxide based semiconductor by a hydrothermal synthesis method in which a zinc oxide based material with a weight ratio of Si being 100 ppm or less is used.

Furthermore, a sixth aspect of the present invention is the method for manufacturing a zinc oxide based substrate according to the fifth aspect characterized in that the method includes the step of heat-processing the zinc oxide based substrate at 1300° C. or more.

According to the present invention, employing a zinc oxide based substrate having low concentrations of impurities including Si and the like makes it possible to prevent undesired impurities from being doped in a zinc oxide based semiconductor layer grown on the substrate.

### BRIEF DESCRIPTION OF DRAWINGS

FIG. 1 shows a cross-sectional view of a zinc oxide based semiconductor element according to an embodiment of the present invention.

FIG. 2 is a schematic diagram showing a unit cell of a hexagonal crystal structure.

FIG. 3 is a schematic diagram of an entire MBE apparatus.

FIG. 4 is a diagram showing results of an experiment conducted to find a relationship between a concentration of impurity Si at interface and a concentration of impurity Si inside a layer.

FIG. 5 is a diagram showing results of an experiment conducted to find the impurity concentration of a zinc oxide based semiconductor layer grown on a zinc oxide substrate according to a first example.

FIG. 6 is a diagram showing results of an experiment conducted for segregation of Li to a main surface of a zinc oxide substrate by heating the zinc oxide substrate.

FIG. 7 is a diagram showing results of an experiment conducted to find diffusion, into a zinc oxide based semiconductor layer, of Li segregated to the surface of the zinc oxide substrate.

FIG. 8 is a diagram showing results of an experiment conducted to find the impurity concentration of a zinc oxide based semiconductor layer grown on a zinc oxide substrate according to a second example.

FIG. 9 is a diagram showing results of an experiment conducted to find the impurity concentration of a zinc oxide based semiconductor layer grown on a zinc oxide substrate according to a first comparative example.

### DETAILED DESCRIPTION OF THE INVENTION

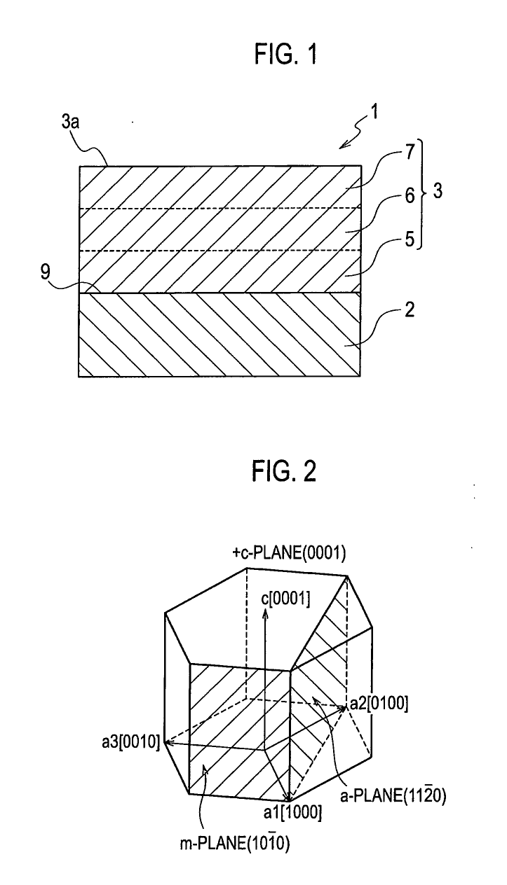

Hereinbelow, an embodiment of the present invention will be described with reference to the drawings. FIG. 1 shows a cross-sectional view of a zinc oxide based semiconductor element according to the embodiment of the present invention. Note that a zinc oxide base is a concept including ZnO and MgZnO.

As shown in FIG. 1, a zinc oxide based semiconductor element 1 according to the embodiment includes a zinc oxide based substrate 2, and a zinc oxide based semiconductor layer 3. The zinc oxide based semiconductor layer 3 has a ZnO semiconductor layer 5, an MgZnO semiconductor layer 6, and a ZnO semiconductor layer 7 which are epitaxially grown in this order.

The zinc oxide based substrate 2 is provided to epitaxially grow the zinc oxide based semiconductor layer 3 thereon. The zinc oxide based substrate 2 is formed of MgₓZn₁₋ₓO. Here, X satisfies that 0≦X≦1, or preferably, 0≦X≦0.5. X=0 means no Mg contained. In addition, since excessively large X changes the crystal structure, it is preferable that X be 0.5 or less.

In the zinc oxide based substrate 2, concentrations of impurities being Group I elements such as of Li are 1×10¹⁶ ⁻³ or less. Some other Group I elements are Na, K, Rb, and Fr. Meanwhile, in the zinc oxide based substrate 2, concentrations of impurities being Group IV elements such as of Si are 1×10¹⁷ cm⁻³ or less. Some other Group IV elements are C, Ge, Sn, and Pb. The zinc oxide based substrate 2 is configured so that a main surface 9 of the zinc oxide based substrate 2 extends approximately along the c-plane.

Subsequently, a hexagonal crystal structure, called wurtzite, which constitutes the aforementioned zinc oxide based substrate 2 will be described. FIG. 2 is a schematic diagram showing a unit cell of a hexagonal crystal structure.

As shown in FIG. 2, a hexagonal crystal structure is in a form of a hexagonal prism. The central axis of the hexagonal prism is the c-axis [0001], and directions which are perpendicular to the c-axis and respectively pass vertices of the hexagon not adjacent to each other in a plan view are the aₗ-axis [1000], the a₂-axis [0100], and the a₃-axis [0010]. By using the miller indices, the +c-plane can be expressed as (0001), and the −c-plane can be expressed as (000-1). Further, by using the miller indices, the m-plane, which is a side plane of the hexagonal prism, is expressed as (10-10), the a-plane, which is a plane passing through a pair of edges which are not adjacent to each other, is expressed as (11-20), normal vectors for the m-plane and the a-plane are expressed as the m-axis and the a-axis. Atoms of Group II elements of Mg or Zn are provided at the vertices and the center of the hexagon-shaped +c-plane, while oxygen atoms are provided at the vertices and the center of the −c-plane.

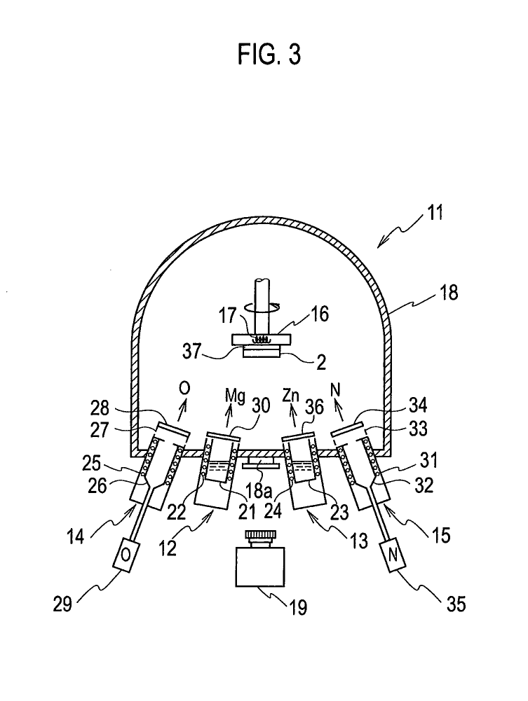

Next, an MBE apparatus 11 for manufacturing the zinc oxide based semiconductor layer 3 on the zinc oxide based substrate 2 will be described with reference to FIG. 3. FIG. 3 is a schematic diagram of an entire MBE apparatus.

As shown in FIG. 3, the MBE apparatus 11 includes multiple cells 12 to 15, a substrate holder 16, a heater 17, a chamber 18, a thermometric device (thermography) 19, and a vacuum pump (illustration is omitted).

The Knudsen cell 12 is configured to form a molecular beam from an elemental metal of magnesium and to supply the molecular beam. The Knudsen cell 12 includes a crucible 21 made of PBN, a heater 22 for heating the crucible 21, and a shutter 30. The crucible 21 holds an elemental metal of magnesium with high purity (6N: 99.9999%, for example).

The Knudsen cell 13 is configured to form a molecular beam from an elemental metal of zinc and to supply the molecular beam. The Knudsen cell 13 includes a crucible 23 made of PBN, a heater 24 for heating the crucible 23, and a shutter 36. The crucible 23 holds an elemental metal of zinc with high purity (7N: 99.99999%, for example).

The radical cell 14 is configured to supply oxygen radicals. The radical cell 14 includes a coil 25, an electric discharge tube 26, a parallel electrode 27, and a shutter 28. The coil 25 changes oxygen to the oxygen radicals with generation of RF plasma. The electric discharge tube 26 is formed of quartz a part of which on a substrate holder 16 side is opened. The parallel electrode 27 is used to trap unwanted ions. The shutter 28 allows or blocks provision of the oxygen radicals. Note that an oxygen source 29 for supplying the oxygen gas is connected to the radical cell 14. In this respect, O₂ gas or O₃ gas can be used as the oxygen gas. In a case where the O₃ gas is used as the oxygen gas, the generation of the plasma can be omitted.

The radical cell 15 is configured to supply nitrogen radicals for changing the zinc oxide based semiconductor layer 3 into p type. The radical cell 15 includes a coil 31, an electric discharge tube 32, a parallel electrode 33, and a shutter 34. The configurations of the coil 31, the electric discharge tube 32, the parallel electrode 33, and the shutter 34 are almost the same as those of the coil 25, the electric discharge tube 26, the parallel electrode 27, and the shutter 28 of the radical cell 14, so that the description thereof is omitted. Moreover, a nitrogen source 35 for supplying the nitrogen gas is connected to the radical cell 15. In this respect, discharging alone N₂ gas, NO gas, NO₂ gas, N₂O gas, or NH₃ as the nitrogen gas is applicable.

The substrate holder 16 is configured to hold the zinc oxide based substrate 2. The substrate holder 16 is supported at a central portion in the chamber 18 so as to be rotatable. The heater 17 is configured to heat the zinc oxide based substrate 2, and formed of a carbon heater which is SiC-coated so as not to be oxidized. The thermometric device 19 is configured to measure the temperature of the zinc oxide based substrate 2 by use of infrared radiation emitted from the zinc oxide based substrate 2 via a window 18a of the chamber 18. The thermometric device 19 is formed of a pyrometer or a thermo viewer. In the case of the thermo viewer, it is necessary to use BaF₂, for the material forming the window 18a, which allows light with the wave length of 8 μm to 14 μm to transmit therethrough. In order to allow the thermometric device 19 to accurately measure the temperature, an infrared radiation shield film 37 is provided on the back surface (surface opposite from the main surface 9) of the zinc oxide based substrate 2, the infrared radiation shield film 37 configured to shield the infrared radiation from the substrate holder 16 or the heater 17. As an example, the infrared radiation shield film 37 is obtained by stacking a titanium (Ti) layer of approximately 10 nm in thickness and a platinum (Pt) layer of approximately 100 nm in thickness.

Subsequently, a method of manufacturing the zinc oxide based semiconductor element 1 according to the embodiment will be described.

Firstly, a zinc oxide material formed of ZnO or MgZnO is dissolved in a solution containing LiOH and KOH to manufacture an ingot made of the zinc oxide based material by the hydrothermal synthesis method. It is preferable that weight ratio of Si in the zinc oxide based material used here be 100 ppm or less in order to set the Si concentration in the zinc oxide based substrate to 1×10¹⁷ cm⁻³. Then, the ingot is sliced into a desired thickness to form the zinc oxide based substrate. In this respect, the thickness of the zinc oxide based substrate is not particularly limited, but the thickness of approximately 300 μm to approximately 500 μm is preferable in order to make it easy to discharge impurities being Group I elements in heat processing to be described later.

Thereafter, the zinc oxide based substrate is heat-processed at a temperature of 1300° C. or more to discharge Group I elements from the zinc oxide based substrate until the concentrations of impurities being Group I elements satisfy the condition described above. Here, the temperature in the heat processing has to be 1300° C. or more, and also has to be equal to or less than the sublimation temperature of ZnO or MgZnO (approximately 1600° C.). By processing the main surface 9 with the CMP (chemical mechanical polishing) method so that the main surface 9 extends approximately along the c-plane, the zinc oxide based substrate 2 is completely manufactured.

Subsequently, the +c-plane of the aforementioned zinc oxide based substrate 2 is etched with hydrochloric acid, cleaned with pure water, and dried with dry nitrogen. Thereafter, the zinc oxide based substrate 2 attached to the substrate holder 16 together with the infrared radiation shield film 37 is introduced in the chamber 18 of the MBE apparatus 11 through a load lock (illustration is omitted).

Then, air inside the chamber 18 is discharged to be vacuum until having a pressure of approximately 1×10⁻⁷ Pa. Subsequently, while keeping the vacuum state, the zinc oxide based substrate 2 is heated for about 30 minutes at approximately 900° C. The temperature of the zinc oxide based substrate 2 is measured in a condition that ε=0.18 in the case of using a pyrometer, or ε=0.71 in the case of using a thermo viewer (the same applies to descriptions below).

Thereafter, the temperature of the zinc oxide based substrate 2 is decreased to a desired temperature. In this respect, the desired temperature is a temperature required for the main surface 9 of the zinc oxide based substrate 2 and a growing surface of the zinc oxide based semiconductor layer 3 to be kept flat so that n type impurities are prevented from being contained in the zinc oxide based semiconductor layer 3. For example, the temperature of the zinc oxide based substrate 2 is set to approximately 800° C. or more in a case of growing an Mg_{Y}Zn_{1-y}O based semiconductor layer where Y is approximately 0.2. Note that, in the case where Y≦0.2, the temperature of the zinc oxide based substrate 2 is preferably set to 800° C. or less, or more preferably, to 750° C. or more, whereas in the case where Y>0.2, the temperature of the zinc oxide based substrate 2 is preferably set to 800° C. or more.

Subsequently, the Knudsen cell 12 is heated to approximately 300° C. to approximately 400° C. to sublimate an elemental metal of magnesium, and then supplies a molecular beam of magnesium to the +c-plane of the zinc oxide based substrate 2. In addition, the Knudsen cell 13 is heated to approximately 260° C. to approximately 280° C. to sublimate an elemental metal of zinc, and then supplies a molecular beam of zinc to the zinc oxide based substrate 2. Moreover, RF plasma is generated in the radical cells 14 and 15. The oxygen gas and the nitrogen gas are subjected to sputtering with the RF plasma, and thereby the oxygen radicals and the nitrogen radicals are produced. Then, the oxygen radicals and the nitrogen radicals are supplied to the zinc oxide based substrate 2 with their supply amounts being adjusted.

In this respect, in the zinc oxide based semiconductor layer 3, the valance band is located so deep as approximately 7.5 eV from the vacuum level, which means that a large energy is required to form holes in the valance band. Forming holes in the valance band makes crystals unstable, thereby causing the zinc oxide based semiconductor layer 3 to have a strong self-compensation effect with which donors to compensate holes are formed. Here, in many cases, the self-compensation effect is deviated from induction of point defect which occurs because p type impurities serving as acceptors are contained in the zinc oxide based semiconductor layer 3. In a case where the zinc oxide based semiconductor layer 3 with such strong self-compensation effect is formed by the MBE apparatus 11 which generates RF plasma in the electric discharge tubes 26 and 32 formed of quartz, n type impurities such as silicon, aluminum, and boron come from the electric discharge tubes 26 and 32 and are likely to be captured in the zinc oxide based semiconductor layer 3. In the embodiment, however, by setting the temperature of the zinc oxide based substrate 2 in the above described manner, it is possible to keep the growing surface of the zinc oxide based semiconductor layer 3 flat, and thus to prevent the n type impurities from being captured. The reason why making the growing surface flat prevents the n type impurities from being captured is not clear. However, considering that nitrogen is more likely captured by the +c-plane, it seems that the +c-plane which is used in the main in the present invention has a system to eliminate cations (for example, existence of polarization charges which causes the +c-plane to be positively charged.)

In addition, since the zinc oxide based substrate 2 is heat-processed before growing the zinc oxide based semiconductor layer 3 thereon in order to reduce the concentrations of impurities including Li and the like, it is possible to prevent diffusion of the impurities including Li and the like into the zinc oxide based semiconductor layer 3. As a result, it is possible to reduce the concentrations of undesired impurities in the zinc oxide based semiconductor layer 3.

Thereafter, the above materials are supplied for a predetermined time period until the desired thickness is obtained. Thus, the zinc oxide based semiconductor layer 3 in which the concentrations of impurities including Li and the like are controlled is formed. In this manner, the zinc oxide based semiconductor element 1 is completed.

As described above, in the embodiment, the concentrations of impurities being Group IV elements in the zinc oxide based substrate 2 are kept to 1×10¹⁷ cm⁻³ or less. This allows the concentrations of impurities being Group IV elements in the grown zinc oxide based semiconductor layer 3 to be reduced. In addition, the concentrations of impurities being Group I elements in the zinc oxide based substrate 2 are kept to 1×10¹⁶ cm⁻³ or less. This allows the concentrations of impurities being Group I elements in the grown zinc oxide based semiconductor layer 3 to be reduced.

As a result of these, it becomes easy to make the zinc oxide based semiconductor layer 3 to have a desired impurity concentration, and particularly to achieve changing the zinc oxide based semiconductor layer 3 into p type, which has been hardly achievable.

### (Experiment Conducted for Concentration of Impurity Si at Interface and Inside Layer)

An experiment conducted to find a relationship between the concentration of the impurity Si at interface of a zinc oxide based semiconductor and the concentration of the impurity Si inside a layer of the zinc oxide based semiconductor will be described.

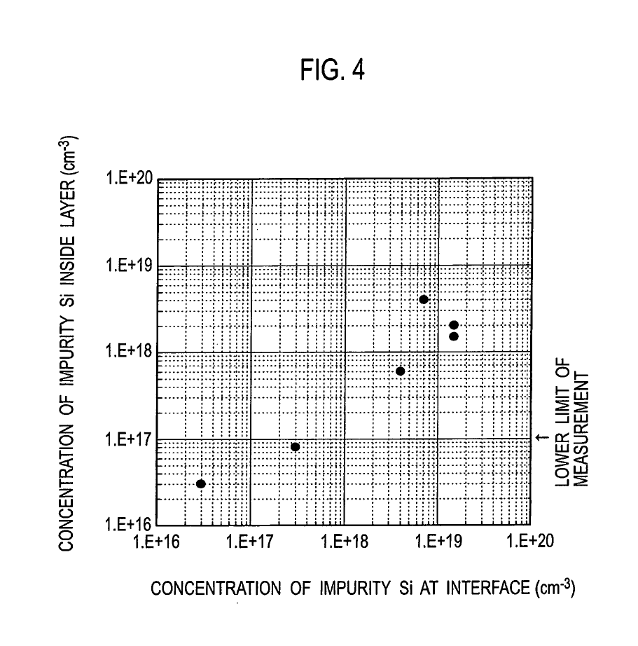

In this experiment, the concentration of the impurity Si at the interface of the zinc oxide based semiconductor and the concentration of the impurity Si inside the layer of the zinc oxide based semiconductor were measured by the SIMS method. The results of the experiment are shown in FIG. 4. In FIG. 4, the abscissa represents the concentration of the impurity Si at the interface (unit: cm⁻³), while the ordinate represents the concentration of the impurity Si inside the layer (unit: cm⁻³). As shown in FIG. 4, it is found that as the concentration of the impurity Si at the interface becomes higher, the concentration of the impurity Si inside the layer becomes higher. With this finding, it is found that the Si at the interface diffuses inside the layer. Accordingly, it is found that reducing the concentration of the impurity Si of the zinc oxide based substrate prevents the diffusion of Si into the zinc oxide based semiconductor layer and enables reduction of the concentration of the impurity Si in the zinc oxide based semiconductor layer.

### (Experiment Conducted for Concentration of Impurity Si Inside Zinc Oxide Based Substrate)

Subsequently, an experiment conducted to find a relationship between the Si concentration in a zinc oxide based substrate and the impurity concentration in a zinc oxide based semiconductor layer grown on the zinc oxide based substrate will be described.

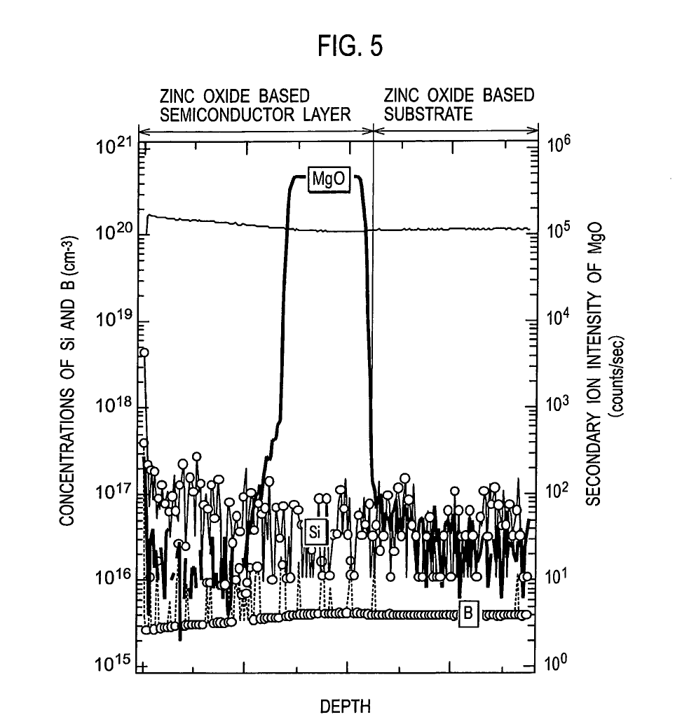

In the present experiment, the zinc oxide based substrate (ZnO substrate) was formed by the hydrothermal synthesis method by using a zinc oxide based material with the weight ratio of Si of 100 ppm or less. A specimen (hereinafter referred to as first example) was formed by epitaxially growing the zinc oxide based semiconductor layer on the zinc oxide based substrate by a MBE apparatus. The zinc oxide based semiconductor layer thus grown has a structure in which an MgZnO semiconductor layer and a ZnO semiconductor layer are stacked in this order from the substrate side. The first example was measured, by the SIMS method, for the Si concentration, the B concentration, and the secondary ion intensity of MgO. The results of the experiment for the first example are shown in FIG. 5. In FIG. 5, the ordinate on the left represents the concentrations of Si and B (unit: cm⁻³), whereas the ordinate on the right represents the secondary ion intensity of MgO (unit: counts/sec). The abscissa represents the depth from the surface. Note that a region where the secondary ion intensity of MgO is large corresponds to the MgZnO semiconductor layer of the grown zinc oxide based semiconductor layer.

As shown in FIG. 5, it is found that the Si concentration inside the zinc oxide based substrate of the first example is 1×10¹⁷cm⁻³or less. It is thus found that the Si concentration inside zinc oxide based semiconductor layer grown on the zinc oxide based substrate is also approximately 1×10¹⁷ cm⁻³ or less. From these findings, it is found that setting the Si concentration inside the zinc oxide based substrate to 1×10¹⁷ cm⁻³ or less prevents the diffusion of Si into the zinc oxide based semiconductor layer and allows the Si concentration inside the zinc oxide based semiconductor layer to be 1×10¹⁷ cm⁻³ or less. According to these results, it is easily presumable that the concentrations of other impurities being Group IV elements, i.e., C, Ge, Sn, and Pb inside the zinc oxide based substrate have to be 1×10¹⁷ cm⁻³ or less.

Moreover, according to other experiments conducted by the inventors of the present application, it is found that the zinc oxide based semiconductor layer can be changed into p type by being doped with p type impurities such as nitrogen, as long as the Si concentration in the zinc oxide based semiconductor layer is 1×10¹⁷ cm⁻³ or less. It is further found that using the zinc oxide based semiconductor layer thus changed into p type allows achievement of a zinc oxide based semiconductor element which can emit light.

### (Experiment Conducted for Segregation of Li)

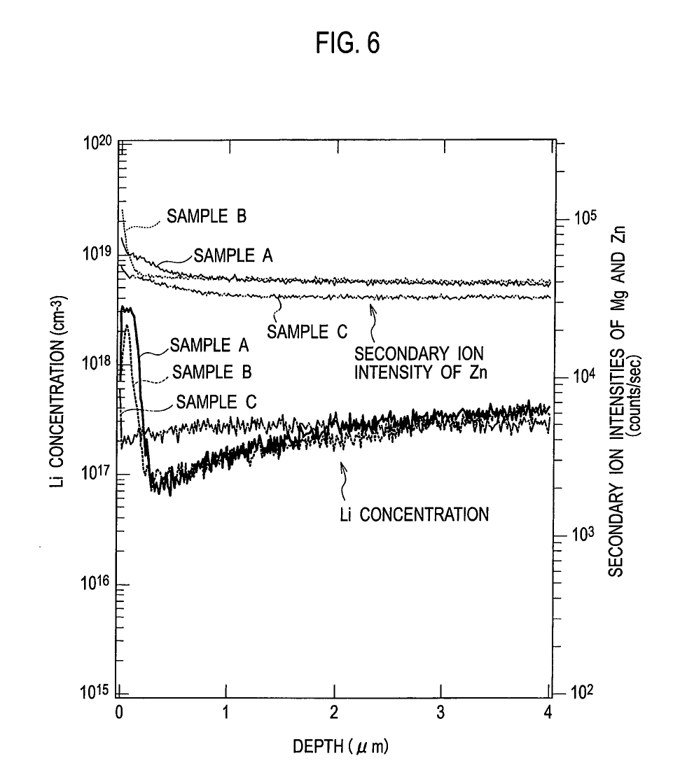

Next, an experiment conducted for segregation of Li to the main surface (surface) of the zinc oxide based substrate by heating the zinc oxide based substrate will be described. In this experiment, the followings were measured by the SIMS method; the Li concentration at the +c-plane of a zinc oxide based substrate which had a protective film formed thereon and which was heat-processed at 1000° C. (hereinafter the substrate is referred to as Sample A); the Li concentration at the −c-plane of a zinc oxide based substrate which had a protective film formed thereon and which was heat-processed at 1000° C. (hereinafter the substrate is referred to as Sample B); and the Li concentration at the +c-plane of a zinc oxide based substrate which was not heat-processed (hereinafter the substrate is referred to as Sample C). The results of the experiment are shown in FIG. 6. In FIG. 6, the ordinate on the left represents the Li concentration (unit: cm⁻³), whereas the abscissa represents the depth from the main surface of each zinc oxide based substrate (unit: μm).

As shown in FIG. 6, it is found that Sample C which is not heat-processed has almost no change in the Li concentration on the main surface, and thus has no segregation of Li. On the other hand, Sample A and Sample B which are heat-processed each have the Li concentration on the main surface (at the depth of approximately 0.3 μm or less) increased.

From this experiment, it is found that heat-processing the zinc oxide substrate can segregate Li to the main surface so that the Li concentration becomes high. Furthermore, it is presumable that heat-processing the zinc oxide substrate at a temperature around or higher than the boiling point of Li not only allows the segregation of Li to the main surface of the zinc oxide substrate, but allows vaporization and elimination of Li.

### (Experiment Conducted for Diffusion of Li)

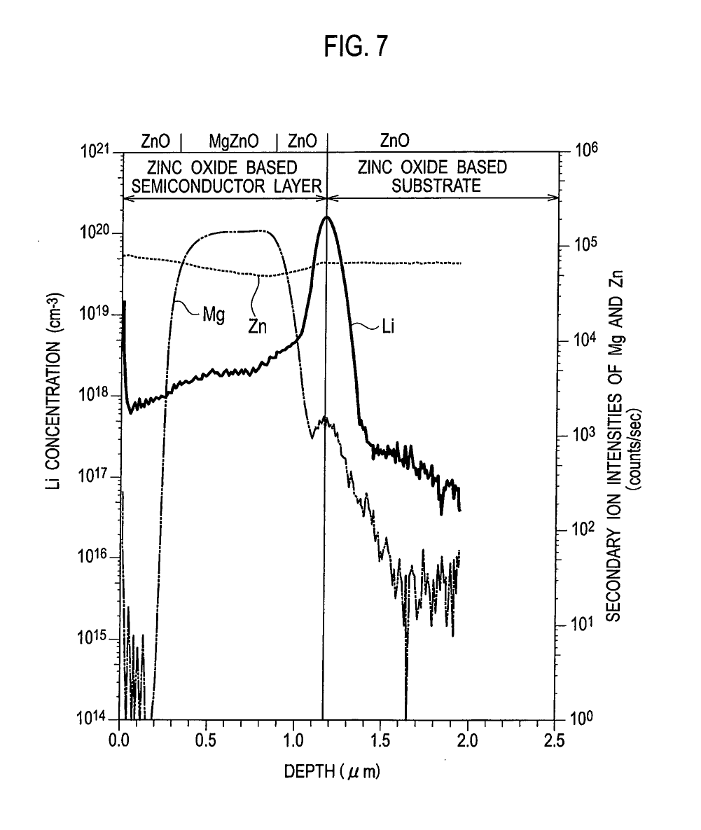

Next, an experiment conducted to find diffusion, into a zinc oxide based semiconductor layer, of Li segregated to the vicinity of the main surface of a zinc oxide based substrate (ZnO substrate) will be described. A specimen used in this experiment was obtained by using a MBE apparatus to stack in order a ZnO semiconductor layer, an MgZnO semiconductor layer, and a ZnO semiconductor layer on a zinc oxide based substrate which is heat-processed at approximately 1300° C. The Li concentrations of each semiconductor layer and of the zinc oxide based substrate of the specimen obtained in this manner (hereinafter referred to as Sample D) were measured by the SIMS method. The results are shown in FIG. 7. In FIG. 7, the ordinate on the left represents the Li concentration (unit: cm⁻³), whereas the abscissa represents the depth from the surface of the zinc oxide based semiconductor layer (unit: μm). Note that, a region which is approximately 1.15 μm or deeper corresponds to the zinc oxide based substrate, while a region which is approximately 1.15 μm or shallower corresponds to the zinc oxide based semiconductor layer.

As shown in FIG. 7, it is found that Li is segregated to the main surface of the zinc oxide based substrate of Sample D so that the Li concentration becomes high. It is particularly found that the Li concentration is very high in a region of the zinc oxide based substrate in the vicinity of the main surface and that the Li concentration gradually decreases as the depth from the main surface of the zinc oxide based substrate increases. Considering these findings, it is found that Li which is segregated to the main surface of the zinc oxide based substrate and which is thus concentrated highly diffuses into the zinc oxide based semiconductor layer.

Based on these facts, it is found that unnecessarily heat-processing the zinc oxide based substrate adversely segregates Li to the main surface of the zinc oxide based substrate and thus causes a large amount of Li to diffuse into the grown zinc oxide based semiconductor layer.

In view of the aforementioned points, an experiment conducted to demonstrate effects of the zinc oxide based substrate according to the present invention will be described next.

### (Experiment Conducted for Concentration of Impurity Li in Zinc Oxide Based Substrate)

Firstly, an experiment conducted to find the relationship between the concentration of impurities including Li and the like in a zinc oxide based substrate and the concentration of impurities including Li and the like in a zinc oxide based semiconductor layer grown on the zinc oxide based substrate will be described.

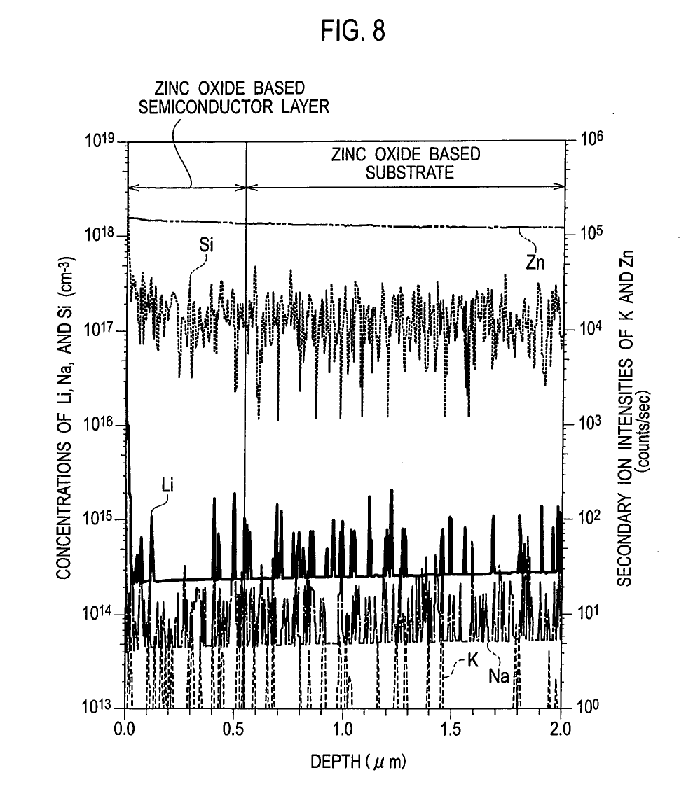

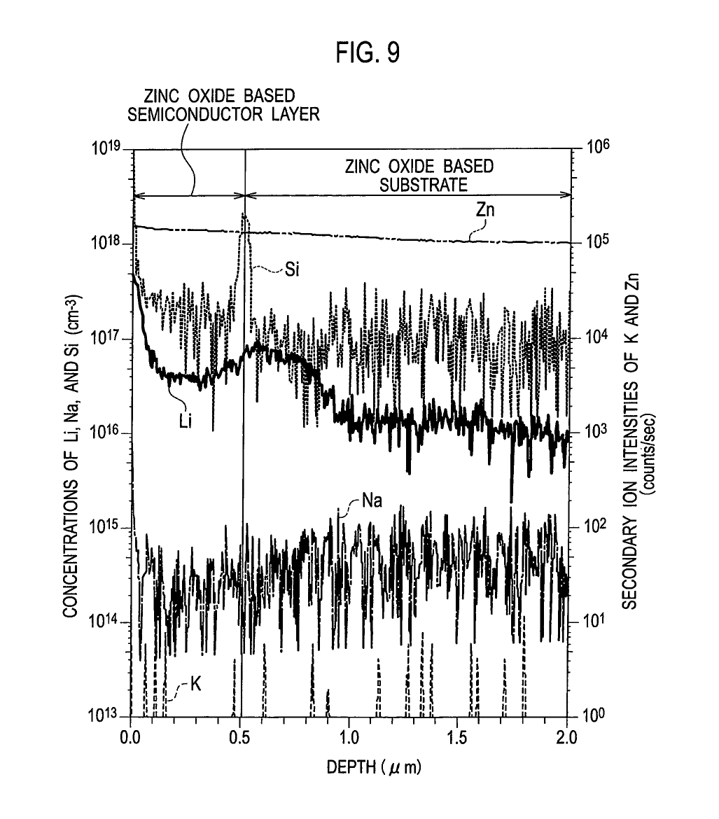

In this experiment, the zinc oxide based semiconductor layer was epitaxially grown on the zinc oxide based substrate (ZnO substrate) by a MBE apparatus. Thereafter, the zinc oxide based substrate and the zinc oxide based semiconductor layer were measured by the SIMS method for the Li concentration, the Si concentration, the Na concentration, the secondary ion intensity of Zn, and the secondary ion intensity of K. A specimen according to the present invention was formed as a second example, and a specimen for comparison was formed as a first comparative example. The results of the experiment for the second example are shown in FIG. 8 while the results of the experiment for the first comparative example are shown in FIG. 9. In FIG. 8 and FIG. 9, the ordinate on the left represents concentrations of Li, Na, and Si (unit: cm⁻³) whereas the ordinate on the right represents secondary ion intensities of Zn and K (unit: counts/sec). The abscissa represents the depth from the surface (unit: μm). Note that, in FIG. 8 and FIG. 9, a region approximately 0.5 μm or deeper corresponds to the zinc oxide based substrate, while a region approximately 0.5 μm or shallower corresponds to the grown zinc oxide based semiconductor layer.

As shown in FIG. 8, the zinc oxide based substrate according to the second example has the Li concentration of about 1×10¹⁵ cm⁻³ or less and the Na concentration of about 3×10¹⁴ cm⁻³ or less. Since the signal intensity for the Li concentration and the signal intensity for the Na concentration hit the bottom of the graph most of the time, it is found that these concentrations reach the limitation of the SIMS measurement. In addition, the zinc oxide based semiconductor layer grown on the zinc oxide based substrate according to the second example has the Li concentration of about 1×10¹⁵ cm⁻³ or less and the Na concentration of about 3×10¹⁴ cm⁻³ or less. As in the case of the substrate, it is found that these concentrations reach or are lower than the limitation of the SIMS measurement. These results show that the sufficient reduction is achieved in the concentrations of impurities Li and Na which are Group I elements in the zinc oxide based semiconductor layer grown on the zinc oxide based substrate according to the second example.

On the other hand, as shown in FIG. 9, it is found that the zinc oxide based substrate according to the first comparative example has a Li concentration larger than approximately 1×10¹⁶ cm⁻³. Also, it is found that the zinc oxide based semiconductor layer grown on the zinc oxide based substrate according to the first comparative example has the Li concentration of about 5×10¹⁶ cm⁻³. Moreover, it is found that the Li concentration is higher at the surface of the zinc oxide based semiconductor layer. As a consequence, the Li concentration in the zinc oxide based semiconductor layer grown on the zinc oxide based substrate is not sufficiently reduced in the first comparative example.

In view of these findings, it is found that the concentrations of impurities Li and Na in the zinc oxide based substrate have to be 1×10¹⁶ cm⁻³ or less. In addition, it is easily presumable from these results that the concentrations of impurities K, Rb, and Fr which are other impurities being Group I elements in the zinc oxide based substrate have to be 1×10¹⁶ cm⁻³ or less. Li is likely to move in the layer as mobile ions under the situation where voltage is applied, as in a device operation. For this reason, it is needless to say that smaller amount of Li is better, preferably, 1×10¹⁵ cm⁻³ or less, or more preferably, 5×10¹⁴ cm⁻³ or less, in terms of device operation.

In addition, as shown in FIG. 8 and FIG. 9, if the Si concentration in the zinc oxide based substrate is 1×10¹⁷ cm⁻³ or more, the Si concentration in the zinc oxide based semiconductor layer also becomes 1×10¹⁷ cm⁻³ or more. With this result, it is found that the Si concentration of the zinc oxide based substrate according to the second example is not capable of reducing the Si concentration of the zinc oxide based semiconductor layer sufficiently.

As described above, the details of the present invention have been described by using the embodiment. However, the present invention is not limited to the embodiment described herein. Accordingly, the technical scope of the present invention should be determined by the description of the scope of claims and the equivalent scope of the description of the scope of claims.

1. A zinc oxide based substrate comprising:
an impurity of a Group IV element of any of Si, C, Ge, Sn, and Pb, the impurity having a concentration of 1×10¹⁷ cm⁻³ or less.

2. A zinc oxide based substrate comprising:
an impurity of a Group I element of any of Li, Na, K, Rb, and Fr, the impurity having a concentration of 1×10¹⁶ cm⁻³ or less; and
an impurity of a Group IV element of any of Si, C, Ge, Sn, and Pb, the impurity having a concentration of 1×10¹⁷ cm⁻³ or less.

3. The zinc oxide based substrate of claim 2, wherein:
the Group I element is Li; and
the Group IV element is Si.

4. The zinc oxide based substrate of claim 1, wherein:
the zinc oxide based substrate is formed of MgₓZn₁₋ₓO (0≦X≦0.5).

5. Method for manufacturing a zinc oxide based substrate comprising:
the step of forming an ingot made of a zinc oxide based semiconductor by a hydrothermal synthesis method in which a zinc oxide based material with a weight ratio of Si being 100 ppm or less is used.

6. The method for manufacturing a zinc oxide based substrate of claim 5, wherein:
the method includes the step of heat-processing the zinc oxide based substrate at 1300° C. or more.

7. The zinc oxide based substrate of claim 2, wherein:
the zinc oxide based substrate is formed of MgₓZn₁₋ₓO (0≦X≦0.5).

8. The zinc oxide based substrate of claim 3, wherein:
the zinc oxide based substrate is formed of MgₓZn₁₋ₓO (0≦X≦0.5).
